(19) United States
(12) Patent Application Publication
(10) Pub. No.: US 2026/0271588 A1
(43) Pub. Date: Sep. 10, 2026

(54) DISPLAY APPARATUS

(71) Applicant: LG Display Co., Ltd., Seoul (KR)

(72) Inventor: Junyoung LEE, Paju-si (KR)

(73) Assignee: LG Display Co., Ltd., Seoul (KR)

(21) Appl. No.: 19/369,280

(22) Filed: Oct. 26, 2025

(30) Foreign Application Priority Data
Mar. 5, 2025 (KR) 10-2025-0027934

(51) Int. Cl. H10K 59/80

(52) U.S. Cl. CPC H10K 59/873

(57) ABSTRACT

The present disclosure relates to a display apparatus. According to an example embodiment of the present disclosure, there is provided a display apparatus including a display panel, a printed circuit board attached to the display panel, at least one plate below the display panel, a buffer member on side surfaces of each of the display panel and at least one plate, and an impact protection film on a lower surface of the at least one plate, in which at least a portion of the impact protection film is disposed between the printed circuit board and the buffer member.

### CROSS REFERENCE TO RELATED APPLICATION

The present application claims priority to Korean Patent Application No. 10-2025-0027934, filed Mar. 5, 2025, the entire contents of which are incorporated herein for all purposes by this reference.

### BACKGROUND

### Technical Field

The present disclosure relates to a display apparatus and more particularly, for example, without limitation, to a display apparatus with improved reliability by minimizing or reducing defects through minimizing or reducing external impacts, vibrations, and the like being transferred.

### Description of the Related Art

As the information society develops, various demands for display apparatuses for displaying images are increasing, and various types of display apparatuses, such as a liquid crystal display (LCD) apparatus and an organic light-emitting diode (OLED) display apparatus, are being utilized.

Generally, a display apparatus includes a display area in which images are displayed and a non-display area formed around the display area. In the display apparatus, the non-display area is also referred to as a bezel area, and consumer demand for a display apparatus with a minimized or reduced bezel area has been increasing recently.

The display apparatus can be formed by assembling a display unit including a window member and a display panel with a storage member or another electronic module. After assembly, the display unit is moved by an operator or through a process line until it is formed into a final electronic device, and during this process, external vibrations or impacts may be transferred.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### SUMMARY

The present disclosure is directed to providing a display apparatus capable of suppressing or preventing contact between a printed circuit board and a plate layer.

The present disclosure is also directed to providing a display apparatus having a structure capable of mitigating external impacts, vibrations, etc.

The present disclosure is also directed to providing a display apparatus with improved reliability by minimizing or reducing defects through minimizing or reducing external impacts, vibrations, and the like being transferred.

Aspects of the present disclosure are not limited to the above aspects, and other technical aspects may be inferred from the following example embodiments.

According to one or more example embodiments of the present disclosure, there is provided a display apparatus including a display panel, a printed circuit board attached to the display panel, at least one plate disposed below the display panel, a buffer member disposed on side surfaces of each of the display panel and the at least one plate, and an impact protection film disposed on a lower surface of the at least one plate, in which at least a portion of the impact protection film is disposed between the printed circuit board and the buffer member.

Detailed matters of other example embodiments are included in the detailed description and accompanying drawings.

According to example embodiments of the present disclosure, it is possible to suppress or prevent contact between the printed circuit board and the plate layer.

According to example embodiments of the present disclosure, the display apparatus having the structure capable of mitigating external impacts and vibrations can be provided.

According to example embodiments of the present disclosure, it is possible to improve reliability by minimizing or reducing defects through minimizing or reducing the transfer of the external impact and heat to the internal components.

According to example embodiments of the present disclosure, it is possible to improve the reliability of the display apparatus, thereby implementing the extended lifetime and low power of the display apparatus and also reducing power consumption.

However, effects obtainable from the present disclosure are not limited to the above effects, and other effects that are not described can be clearly understood based on the following description by those skilled in the art to which the present disclosure pertains.

It is to be understood that both the foregoing general description and the following detailed description of the present disclosure are by way of example and explanatory and are intended to provide further explanation of the disclosure as claimed.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description serve to explain various principles of the disclosure.

FIG. 1 is a configuration diagram of a display apparatus according to one or more example embodiments of the present disclosure.

FIG. 2 is a plan view showing a display panel and a printed circuit board of the display apparatus according to FIG. 1.

FIG. 3 is a cross-sectional view showing a bent state of a display panel according to an example embodiment.

FIG. 4 is a cross-sectional view of one pixel of the display panel according to an example embodiment.

FIG. 5 is a rear view of a display apparatus with a bent display panel according to an example embodiment.

FIG. 6 is a cross-sectional view along line A-A′ in FIG. 5.

FIG. 7 is a cross-sectional view along line B-B′ in FIG. 5.

FIG. 8 is a cross-sectional view of a display apparatus according to an example embodiment.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and convenience.

### DESCRIPTION OF REFERENCE NUMERALS

10: display apparatus
DA: display area
NDA: non-display area
100: display panel
200: polarizing layer
300: cover layer
400: first plate
500: second plate
MPF: metal protection film
SPF: impact protection film
FPCB: printed circuit board
BF: buffer member

### DETAILED DESCRIPTION

Hereinafter, example embodiments will be described with reference to the accompanying drawings. In the specification, where a certain component (or a region, a layer, a portion, etc.) is described as “on,” “connected,” or “coupled to” another component, it means that the certain component may be directly connected/coupled to another component or still another component may be disposed therebetween.

Where time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless a more specific term like “directly” or “immediately” is used together.

The same reference numerals and signs indicate the same or like components even when they are shown in different accompanying drawings from one another. In addition, in the drawings, thicknesses, proportions, and dimensions of components may be exaggerated for effective description of technical contents. The term “and/or” includes all one or more combinations that may be defined by the associated configurations. Further, in the following description of examples or embodiments of the present disclosure, detailed descriptions of well-known functions and components incorporated herein may be omitted where the description of such known functions and components may make the subject matter in some embodiments of the present disclosure rather unclear.

Terms such as “first”, “second”, “A”, “B”, “(A)”, or “(B)” may be used to describe various components, but the components are not limited by the terms. The terms are used only for the purpose of referring to one component separately from another. For example, a first component may be referred to as a second component, and similarly, the second component may also be referred to as the first component without departing from the scopes of the embodiments. The singular includes the plural, and vice versa, unless the context clearly dictates otherwise.

Terms such as “under,” “at a lower side,” “above,” and “at an upper side” may be used to describe the relationship between the components illustrated in the drawings. These terms are relative concepts and are described with respect to directions marked in the drawings.

It should be understood that a term such as “includes”, “has”, “containing”, “constituting” “make up of”, or “formed of” is intended to specify the presence of features, numbers, steps, operations, components, parts, or a combination thereof described in the specification and does not preclude the presence or possible addition of one or more other features, numbers, steps, operations, components, parts, or combinations thereof.

Unless otherwise defined, all terms (including technical and scientific terms) used herein have the same meaning as commonly understood by one of ordinary skill in the art to which example embodiments belong. It should be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, various example embodiments of the present disclosure will be described in detail with reference to the accompanying drawings.

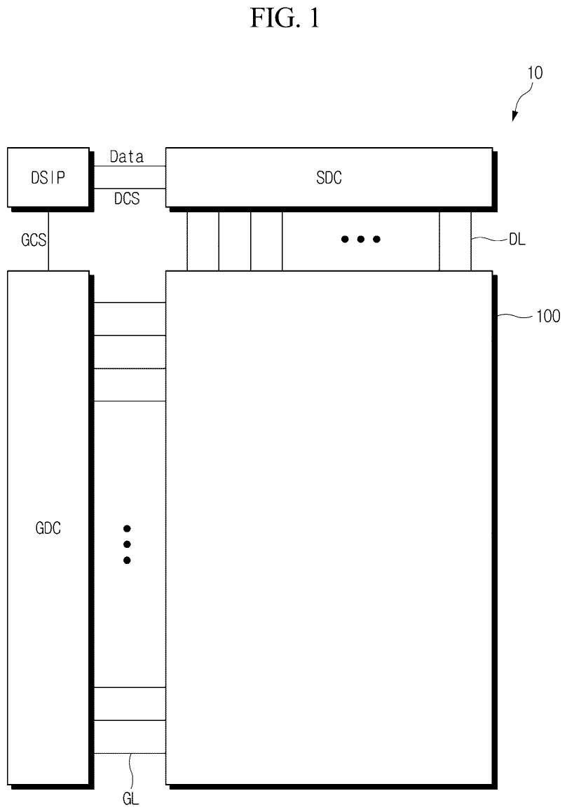

FIG. 1 is a configuration diagram of a display apparatus according to one or more example embodiments of the present disclosure.

A display apparatus 10 according to one or more example embodiments may perform an image display function and a touch detection function (touch input function).

As illustrated in FIG. 1, the display apparatus 10 according to one or more example embodiments may include a display panel 100, a source driving circuit SDC, a gate driving circuit GDC, a display controller DSIP, etc. The embodiments of the present disclosure are not limited thereto.

The display panel 100 may include a base substrate and a plurality of pixels disposed in a display area of the base substrate, and driving units disposed in the non-display area around the display area to drive the pixels.

The pixels may include transistors connected to the driving units by control signal lines, and light-emitting elements connected to the transistors.

The transistors may be turned on or off according to control signals applied through the control signal lines to control the amount of a current applied to the light-emitting elements.

The light-emitting elements may emit light with a brightness corresponding to the amount of a current applied through the transistors. Although the light emitting element may include an organic light emitting diode, the embodiments of the disclosure are not limited thereto. For example, the light emitting element may include an inorganic light emitting diode, a quantum dot diode, a micro LED diode, a mini LED diode, or the like, but the embodiments of the present disclosure are not limited thereto.

For example, the display apparatus 10 according to aspects of the present disclosure may be an organic light emitting display apparatus in which light emitting elements are implemented using organic light emitting diodes (OLED). In another example, the display apparatus 10 according to aspects of the present disclosure may be an inorganic light emitting display apparatus in which light emitting elements are implemented using inorganic material-based light emitting diodes. In further another example, the display apparatus 10 according to aspects of the present disclosure may be a quantum dot display apparatus implemented with quantum dots, which are self-emission semiconductor crystals, as light emitting elements. However, the present disclosure is not limited thereto.

The display panel 100 may have a plurality of data lines DL for carrying data signals (which may be referred to as data voltages or image signals) and a plurality of gate lines GL for carrying gate signals (which may be referred to as scan signals). The display panel 100 may include a plurality of pixels (or pixels). A plurality of pixels may display an image. The plurality of pixels may be arranged by being defined by the plurality of data lines DL and/or the plurality of gate lines GL.

A source driving circuit SDC may drive the plurality of data lines DL, and can supply data signals to the plurality of data lines DL. A gate driving circuit GDC may drive the plurality of gate lines GL, and can supply gate signals to the plurality of gate lines GL.

The display controller DSIP may control the source driving circuit SDC and the gate driving circuit GDC. The display controller DSIP may control the source driving circuit SDC and the gate driving circuit GDC by supplying various driving control signals DCS and GCS to the source driving circuit SDC and the gate driving circuit GDC.

The display controller DSIP may start scanning according to the timing implemented in each frame, convert externally input image data into a data signal format used in the data driving circuit SDC, output the converted image data DATA, and control data driving at an appropriate time according to the scanning.

The display controller DSIP may receive various timing signals including, for example, a vertical synchronization signal, a horizontal synchronization signal, an input data enable signal, a clock signal, etc. to an external device (e.g., a host system) together with the input image data.

The display controller DSIP may not only convert the input image data input from the outside to suit the data signal format used in the source driving circuit SDC and output the converted image data, but also, to control the source driving circuit SDC and the gate driving circuit GDC, receive timing signals such as a vertical synchronization signal, a horizontal synchronization signal, an input data enable signal, or a clock signal, and generate and output various driving control signals DCS and GCS to the source driving circuit SDC and the gate driving circuit GDC.

The source driving circuit SDC may drive the plurality of data lines DL by receiving the image data DATA from the display controller DSIP and supplying the data voltage to the plurality of data lines DL. The source driving circuit SDC may be a data driving circuit, but the embodiments of the present disclosure are not limited thereto. The embodiments of the present disclosure are not limited thereto.

The source driving circuit SDC may be implemented by including at least one source driver integrated circuit (SDIC), but the embodiments of the present disclosure are not limited thereto.

The gate driving circuit GDC may drive the plurality of gate lines GL by supplying a scan signal to the plurality of gate lines GL. The gate driving circuit GDC may be a scan driving circuit, but the embodiments of the present disclosure are not limited thereto. The gate driving circuit GDC may supply gate signals to the plurality of gate lines GL according to timing control of the display controller DSIP. The embodiments of the present disclosure are not limited thereto.

The gate driving circuit GDC may be implemented by including at least one gate driver integrated circuit (GDIC), but the embodiments of the present disclosure are not limited thereto.

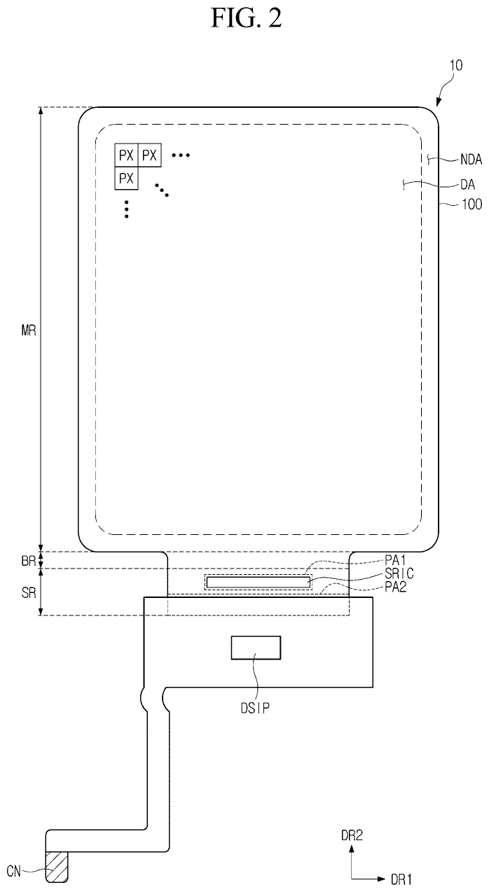

As shown in FIG. 1, the display apparatus 10 according to one or more example embodiments may include a touch panel, a touch driving circuit, a touch controller, and the like to provide a touch sensing function. The touch panel may be formed integrally with the display panel 100, but is not limited thereto. The touch panel may be formed separately on the display panel 100. The touch driving circuit may be integrated with the source driving circuit SDC and included in an integrated circuit (see SRIC in FIG. 2), but the embodiments of the present disclosure are not limited thereto. For example, the touch panel may be disposed outside of the display panel 100, such a touch panel may be referred to as an add-on type. For example, the add-on type of touch panel may be disposed in the display apparatus 10, the touch panel and the display panel 100 may be separately manufactured and combined in an assembly process.

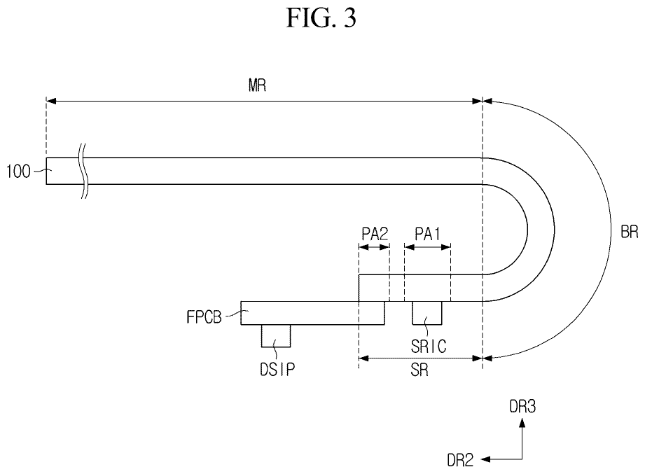

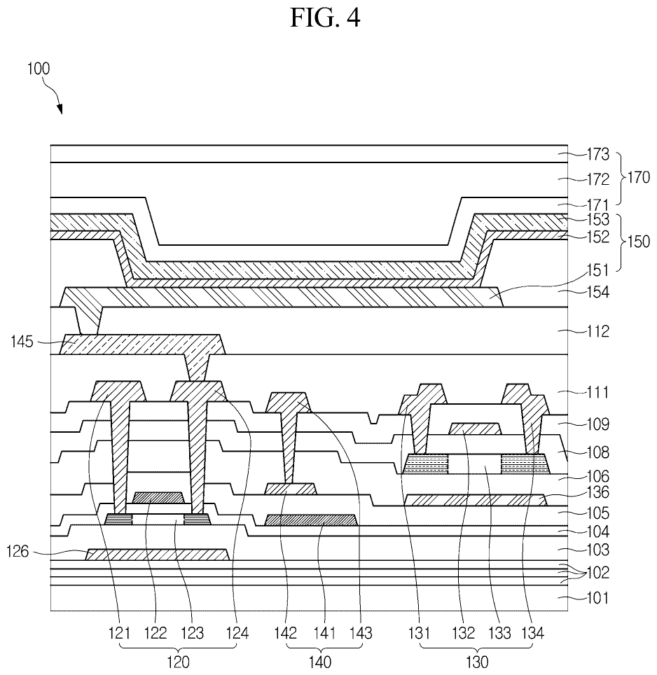

FIG. 2 is a plan view showing a display panel and a printed circuit board of the display apparatus according to FIG. 1. FIG. 3 is a cross-sectional view showing a bent state of a display panel according to an example embodiment. FIG. 4 is a cross-sectional view of one pixel of the display panel according to an example embodiment.

As shown in FIGS. 2 to 4, the display panel 100 may include a display area DA including a plurality of pixels PX and a non-display area NDA outside the display area DA. For example, the non-display area NDA may be disposed around the display area DA. All or a portion of the non-display area NDA may be an area visible from the front surface of the display apparatus 10, or an area that is bent and invisible from the front surface of the display apparatus 10 or an area that is covered by a case or housing (not shown) of the display apparatus 10.

The display area DA may include short sides extending in the first direction DR1 and long sides extending in the second direction DR2. The non-display area NDA may surround the display area DA. The non-display area NDA may be located at one side in the first direction DR1, the other side in the first direction DR1, one side in the second direction DR2, and the other side in the second direction DR2 of the display area DA, but the embodiments of the present disclosure are not limited thereto.

The non-display area NDA located at the other side of the display area DA in the second direction DR2 may extend further from a central portion of the other side in the second direction DR2 toward the other side in the second direction DR2 of the display area DA. A width of the non-display area NDA in the first direction DR1 further extending from the central portion of the other side in the second direction DR2 toward the other side in the second direction DR2 of the display area DA may be smaller than a width of the non-display area NDA in the first direction DR1 adjacent to the other side of the display area DA in the second direction DR2.

The display panel 100 may include a first region MR, a second region SR, and a third region BR between the first region MR and the second region SR.

The display area DA and the non-display area NDA surrounding four surfaces of the display area DA may form the first region MR.

The portion extending further from the central portion of the other side of the display area DA in the second direction DR2 toward the other side of the second direction DR2 may form the third region BR and the second region SR. The second region SR may include a first pad area PA1 and a second pad area PA2 located at an end portion of the other side of the second region SR in the second direction DR2. The first pad area PA1 may be disposed adjacent to the third region BR.

The third region BR may be disposed between the second region SR and the first region MR. The third region BR of the display panel 100 may be bent in a thickness direction (or a third direction DR3). Accordingly, the first region MR and the second region SR may overlap each other in the thickness direction. The display panel 100 may be bent in such a manner that a lower surface of the first region MR faces an upper surface of the second region SR.

For example, the first region MR may be a main region or a display region, but is not limited thereto. For example, the second region SR may be a sub-region, but is not limited thereto. For example, the third region BR may be a bending region or a variable region, but is not limited thereto.

The display apparatus 10 may further include an integrated circuit SRIC disposed in the first pad area PA1 of the second region SR and a printed circuit board FPCB attached to the second pad area PA2 of the second region SR.

A plurality of pads connected to the integrated IC SRIC and the printed circuit board FPCB may be disposed in thr second region SR. For example, the plurality of pads connected to the integrated IC SRIC and the printed circuit board FPCB may be disposed in each of the first pad area PA1 and the second pad area PA2. The integrated IC SRIC may be formed, for example, in the form of a driving chip (IC), but is not limited thereto. An example embodiment describes that the integrated IC SRIC is disposed in a chip-on-plastic manner that the integrated IC SRIC is directly mounted on the display panel 100, but the embodiments of the present disclosure are not limited thereto.

A controller may be disposed on the printed circuit board FPCB. The controller may include at least one controller, but is not limited thereto. Only one controller may be disposed on the printed circuit board FPCB. For example, the controller may be the display controller DSIP, but the embodiments of the present disclosure are not limited thereto. For example, the display controller DSIP may be disposed on the printed circuit board FPCB. When the controller is provided as a plurality of controllers, controllers other than the display controller DSIP may include a touch controller, but the embodiments of the present disclosure are not limited thereto.

The printed circuit board FPCB may further include a connector CN and may be electrically connected to a main circuit board, etc. through the connector CN, but the embodiments of the present disclosure are not limited thereto.

Hereinafter, a cross-sectional structure of the display panel 100 will be described.

The display panel 100 may include a substrate 101, a first thin film transistor 120, a second thin film transistor 130, a light-emitting part 150, and an encapsulation part 170.

The substrate 101 may include a flexible substrate. The substrate 101 may include one or more plastic materials. Since the base substrate 101 of the display panel 100 includes a flexible substrate, the display apparatus 10 may be implemented as a foldable, stretchable, or bendable display apparatus, but is not limited thereto.

The substrate 101 may include a flexible polymer film. For example, the flexible polymer film may be made of any one of polyethylene terephthalate(PET), polycarbonate(PC), acrylonitrile-butadiene-styrene copolymer(ABS), polymethyl methacrylate(PMMA), polyethylene naphthalate(PEN), polyether sulfone(PES), cyclic olefin copolymer(COC), triacetylcellulose(TAC) film, polyvinyl alcohol(PVA) film, polyimide(PI) film, and polystyrene(PS), which is only an example and is not necessarily limited thereto.

A buffer layer 102 may be disposed on the substrate 101. The buffer layer 102 can minimize or delay the diffusion of moisture or oxygen penetrating the substrate 101.

A first light-blocking layer 126 may be disposed on the buffer layer 102. The first light-blocking layer 126 can prevent or block light from transmitting a first semiconductor layer 123 of the first thin film transistor 120. For example, the first light-blocking layer 126 may be disposed to overlap the first semiconductor layer 123.

A first insulating layer 103 may be disposed on the first light-blocking layer 126. The first insulating layer 103 may be disposed to cover the first light-blocking layer 126.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may be disposed to cover a portion of the first insulating layer 103. The first semiconductor layer 123 may include a metal oxide semiconductor, such as indium-gallium-zinc oxide (IGZO), and a silicon-based semiconductor material, such as amorphous silicon, polycrystalline silicon, or the like, but is not limited thereto. The first semiconductor layer 123 may include a channel area, a source area, and a drain area.

The second insulating layer 104 may be disposed on the first semiconductor layer 123.

The first gate electrode 122 may be disposed on the second insulating layer 104. The first gate electrode 122 may be disposed to cover a portion of the second insulating layer 104. The first gate electrode 122 may be disposed on the second insulating layer 104 to overlap the channel area of the first semiconductor layer 123.

A third insulating layer 105 may be disposed on the first gate electrode 122. The third insulating layer 105 may be disposed on the first gate electrode 122 and the first storage electrode 141.

The first source electrode 121 and the first drain electrode 124 may be disposed on the third insulating layer 105.

The first source electrode 121 and the first drain electrode 124 may be electrically connected to the first semiconductor layer 123 through contact holes.

A storage electrode 140 may be disposed to be spaced apart from the first thin film transistor 120. The storage electrode 140 may include a first storage electrode 141, a second storage electrode 142, and a third storage electrode 143.

The second storage electrode 142 may be disposed on the first storage electrode 141. The second storage electrode 142 may be disposed on the third insulating layer 105, and the third insulating layer 105 between the first storage electrode 141 and the second storage electrode 142 may be used as a dielectric to generate a capacitance.

The second thin film transistor 130 may be disposed to be spaced apart from the first thin film transistor 120 and the storage electrode 140. The storage electrode 140 may be disposed between the first thin film transistor 120 and the second thin film transistor 130. The second thin film transistor 130 may include a second source electrode 131, a second gate electrode 132, a second semiconductor layer 133, and a second drain electrode 134.

A second light-blocking layer 136 may be disposed on the same layer as the second storage electrode 142.

A fourth insulating layer 106 may be disposed on the second light-blocking layer 136. The fourth insulating layer 106 may be disposed to cover the second light-blocking layer 136.

The second semiconductor layer 133 may be disposed on the fourth insulating layer 106. The second semiconductor layer 133 may be disposed to cover a portion of the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto.

A fifth insulating layer 108 may be disposed on the second semiconductor layer 133. The fifth insulating layer 108 may be disposed on the second semiconductor layer 133 and the fourth insulating layer 106.

The second gate electrode 132 may be disposed on the fifth insulating layer 108. The second gate electrode 132 may be disposed to cover a portion of the fifth insulating layer 108.

A sixth insulating layer 109 may be disposed on the second gate electrode 132. The sixth insulating layer 109 may be disposed on the second gate electrode 132 and the fifth insulating layer 108.

The first source electrode 121, the first drain electrode 124, the third storage electrode 143, the second source electrode 131, and the second drain electrode 134 may be disposed on the sixth insulating layer 109.

The first thin film transistor 120 may be one of a driving transistor and a switching transistor, and the second thin film transistor 130 may be the other of a driving transistor and a switching transistor. For example, the first thin film transistor 120 may be a driving transistor, and the second thin film transistor 130 may be a switching transistor, but the embodiments of the present disclosure are not limited thereto.

A first protective layer 111 may be disposed on the first source electrode 121 and the first drain electrode 124. The first protective layer 111 may be disposed on the second source electrode 131 and the second drain electrode 134.

The first protective layer 111 may planarize an upper portion of the first thin film transistor 120 and protect the first thin film transistor 120. The first protective layer 111 may be formed of an organic material.

A second protective layer 112 may be disposed on the first protective layer 111. The second protective layer 112 may be formed of the same material as the first protective layer 111, but the embodiments of the present disclosure are not limited thereto.

A connection electrode 145 may be disposed between the first protective layer 111 and the second protective layer 112. The connection electrode 145 may electrically connect the first thin film transistor 120 to the light-emitting part 150.

The light-emitting part 150 may be disposed on the second protective layer 112. The light-emitting part 150 may include an anode electrode 151, an organic layer 152, and a cathode electrode 153.

The anode electrode 151 may be disposed on the second protective layer 112. The anode electrode 151 may be disposed to cover a portion of the second protective layer 112. The anode electrode 151 may be electrically connected to the first thin film transistor 120 through a contact hole formed in the second protective layer 112. The anode electrode 151 may be a reflective electrode that reflects light, but the embodiments of the present disclosure are not limited thereto.

The organic layer 152 may be disposed on the anode electrode 151. Specifically, the organic layer 152 may be disposed on the anode electrode 151 and the bank 154. The organic layer 152 may include one or more light-emitting structures (or light-emitting elements or elements) stacked on the anode electrode 151 in the order or reverse order of a hole transfer layer and an electron transfer layer.

The organic layer 152 may be an organic light-emitting layer, an inorganic light-emitting layer, a quantum dot light-emitting layer, a micro light-emitting diode, a micro mini light-emitting diode, etc., but the embodiments of the present disclosure are not limited thereto.

The cathode electrode 153 may be disposed on the organic layer 152. The cathode electrode 153 may be a transparent electrode that transmits light, but the embodiments of the present disclosure are not limited thereto.

A bank 154 may be disposed to expose the anode electrode 151. The organic layer 152 may be disposed to cover the exposed portion of the anode electrode 151. The bank 154 may define an opening (or a light-emitting area EA of the pixel PX and may be disposed to cover an edge of the anode electrode 151.

When the bank 154 is formed of a material containing black pigment, black dye, or the like, the bank 154 may be a black bank. In this case, it is possible to block external light or light reflected from the outside, thereby further improving brightness of the display apparatus.

The bank 154 serves to define a sub-pixel. Thus, the bank 154 may be made of an insulating material containing a black material. The bank 154 may be made of, for example, a transparent carbon-based mixture. Specifically, the bank 154 may contain carbon black, but is not limited thereto. The bank 154 may also be made of a transparent insulating material.

A spacer may be further disposed on the bank 154.

The encapsulation part 170 may be disposed on the bank 154 or the light-emitting part 150. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic layers and one or more organic layers. For example, the first encapsulation layer 171 and the third encapsulation layer 173 may include an inorganic material, and the second encapsulation layer 172 may include an organic material, but the embodiments of the present disclosure are not limited thereto.

The first encapsulation layer 171 and the third encapsulation layer 173 may include an inorganic insulating material. For example, the first encapsulation layer 171 and the third encapsulation layer 173 may include an inorganic insulating material capable of low-temperature deposition, such as silicon nitride (SiN), silicon oxide (SiO), silicon oxynitride (SiON) and aluminum oxide (Al₂O₃).

The second encapsulation layer 172 may include an organic insulating material, such as acrylic resin, epoxy resin, polyimide, polyethylene and silicon oxycarbide (SiOC).

Although not shown, a touch part capable of detecting a user's touch may be further disposed on the encapsulation part 170.

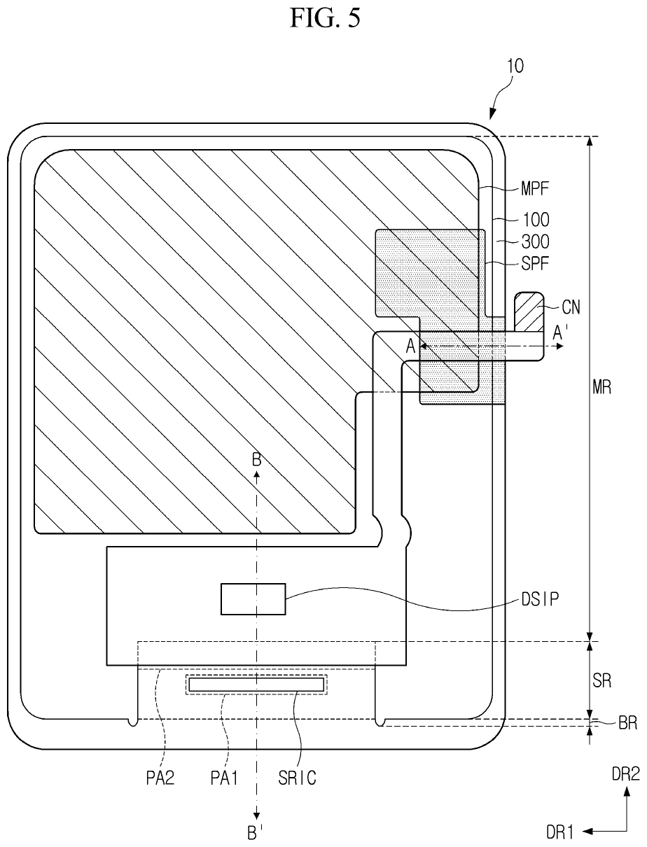

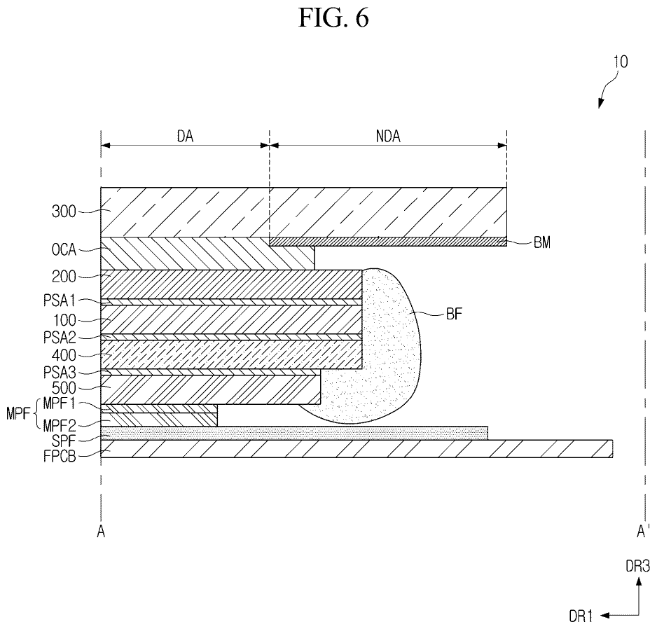

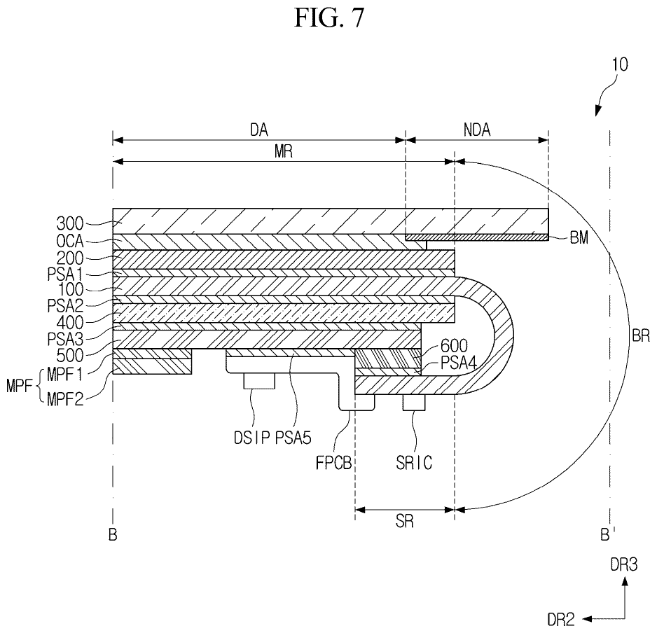

FIG. 5 is a rear view of the display apparatus with a bent display panel according to an example embodiment of the present disclosure. FIG. 6 is a cross-sectional view along line A-A′ in FIG. 5. FIG. 7 is a cross-sectional view along line B-B′ in FIG. 5.

FIG. 5 shows a rear view of the display apparatus 10 as viewed from the rear after the display panel 100 is bent as in FIG. 3.

As shown in FIGS. 5 to 7, the display apparatus 10 may include a plurality of stacked members. The display apparatus 10 may further include a polarizing layer 200 disposed on an upper surface of the display panel 100, a cover layer 300 disposed on an upper surface of the polarizing layer 200, a first plate 400 disposed on a lower surface (rear surface) of the display panel 100, and a second plate 500 disposed on a lower surface of the first plate 400.

However, the embodiments of the present disclosure are not limited thereto, and although not shown, the display apparatus 10 may further include a metal frame disposed below the second plate 500, a system frame capable of storing the stacked members, etc.

The display apparatus 10 may further include bonding layers disposed between stacked members. Specifically, the display apparatus 10 may further include the bonding layers disposed between the display panel 100, the polarizing layer 200, the cover layer 300, the first plate 400, and the second plate 500 to fixedly bond the components. The bonding layers may include the optical adhesive layer OCA, a first bonding layer PSA1, a second bonding layer PSA2, and a third bonding layer PSA3, but is not limited thereto.

The optical adhesive layer OCA may be disposed between the polarizing layer 200 and the cover layer 300. The optical adhesive layer OCA may fixedly adhere the polarizing layer 200 and the cover layer 300.

The optical adhesive layer OCA may include a transparent adhesive. For example, the transparent adhesive may be an optically clear adhesive or an optically clear resin, but the embodiments of the present disclosure are not limited thereto.

The first bonding layer PSA1 may be disposed between the display panel 100 and the polarizing layer 200. The first bonding layer PSA1 may fixedly adhere the display panel 100 and the polarizing layer 200.

The second bonding layer PSA2 may be disposed between the first plate 400 and the display panel 100. The second bonding layer PSA2 may fixedly adhere the first plate 400 and the display panel 100.

The third bonding layer PSA3 may be disposed between the first plate 400 and the second plate 500. The third bonding layer PSA3 may fixedly adhere the first plate 400 and the second plate 500.

Each of the first bonding layer PSA1, the second bonding layer PSA2, and the third bonding layer PSA3 may include an adhesive or a transparent adhesive, but the embodiments of the present disclosure are not limited thereto. For example, the transparent adhesive may be an optically clear adhesive, an optically clear resin, or a pressure sensitive adhesive, but the embodiments of the present disclosure are not limited thereto.

The polarizing layer 200 may be disposed on the display panel 100. The first bonding layer PSA1 may be disposed between the polarizing layer 200 and the display panel 100. The polarizing layer 200 may polarize light emitted from the display panel 100 at a polarization angle. The polarizing layer 200 may emit light polarized at the polarization angle to the outside. The polarizing layer 200 may include a function of blocking reflection of light not including the light polarized at the polarization angle among external light.

The polarizing layer 200 may include a first phase retardation layer, a second phase retardation layer on the first phase retardation layer, and a polarizing layer on the second phase retardation layer, but the embodiments of the present disclosure are not limited thereto. FIG. 6 shows an example in which the polarizing layer 200 and the display panel 100 are separated, but the embodiments of the present disclosure are not limited thereto, and the polarizing layer 200 may be included in the display panel 100.

The cover layer 300 may be disposed on the polarizing layer 200. The optical adhesive layer OCA may be disposed between the polarizing layer 200 and the cover layer 300.

The cover layer 300 can protect members (e.g., the display panel 100 and the like) disposed below the cover layer 300 from the outside. The cover layer 300 can protect the polarizing layer 200.

The cover layer 300 may be formed of a glass material including glass or quartz, but the embodiments of the present disclosure are not limited thereto. The cover layer 300 may be a cover layer formed by chemical reinforcement, but the embodiments of the present disclosure are not limited thereto. The cover layer 300 may be a cover window, a window cover, or a cover member, but the embodiments of the present disclosure are not limited thereto. The embodiments of the present disclosure are not limited thereto. The cover layer 300 may be disposed in the non-display area NDA and the display area DA.

The cover layer 300 may be formed of a glass material, and in this case, the cover layer 300 can be damaged by an external force, resulting in glass fragments. To prevent or suppress the shattering of the glass fragments due to the damage to the cover layer 300 or increase the durability of the cover layer 300, the display apparatus 10 may further include at least one additional layer on the cover layer 300. The embodiments of the present disclosure are not limited thereto.

The display apparatus 10 may further include a black matrix BM. The black matrix BM may define the non-display area NDA of the display apparatus 10. That is, the black matrix BM may be disposed in the non-display area NDA. The black matrix BM may block light from leaking to the non-display area NDA.

The black matrix BM may be disposed on a lower surface (rear surface) of the cover layer 300. Specifically, the black matrix BM may be disposed on a lower surface (rear surface) of the cover layer 300 in the non-display area NDA. The black matrix BM may be disposed to protrude from the cover layer 300 toward an optical adhesive layer OCA in the non-display area NDA. A step may be caused by the black matrix BM, but the step can be eliminated by the optical adhesive layer OCA. In this case, the black matrix BM may be disposed between the cover layer 300 and the optical adhesive layer OCA.

The black matrix BM may be formed of a photosensitive organic material with a black pigment added thereto, but the embodiments of the present disclosure are not limited thereto. The black pigment may include carbon black, titanium oxide, or the like, but the embodiments of the present disclosure are not limited thereto.

The first plate 400 may be disposed below the display panel 100. The first plate 400 may be disposed below the display panel 100 to support the display panel 100. The first plate 400 may have a strength and thickness greater than or equal to a predetermined level or more to supplement the rigidity of the display panel 100. The first plate 400 can suppress wrinkles occurring on the display panel 100.

The first plate 400 may include a material capable of supporting the display panel 100. For example, the first plate 400 may include polyethylene terephthalate (PET), polyimide (PI), or polycarbonate (PC), but the embodiments of the present disclosure are not limited thereto. The first plate 400 may be formed of a single layer, but is not limited thereto, and may also be formed of a plurality of layers.

The second plate 500 may be disposed below the first plate 400. The second plate 500 may be formed of a single layer, but is not limited thereto, and may also be formed of a plurality of layers.

The second plate 500 may include metal. However, the embodiments of the present disclosure are not limited thereto, and for example, the second plate 500 may include one or more materials selected from the group consisting of stainless steel (SUS), glass, ceramic, and metal, or a combination thereof, but the embodiments of the present disclosure are not limited thereto.

The display apparatus 10 may further include a third plate 600. The third plate 600 may be disposed on the second region SR of the display panel 100. The third plate 600 may be disposed between the first region MR and the second region SR of the bent display panel 100. For example, the third plate 600 may be disposed on the third region BR of the bent display panel 100. The third plate 600 may be disposed below the second plate 500 to face the second plate 500.

A fourth bonding layer PSA4 may be disposed between the second region SR of the display panel 100 and the third plate 600. The display panel 100 and the third plate 600 may be fixedly adhered through the fourth bonding layer PSA4. Specifically, the second region SR of the display panel 100 and the third plate 600 may be fixedly adhered through the fourth bonding layer PSA4. The fourth bonding layer PSA4 may include an adhesive, a transparent adhesive, a pressure-sensitive adhesive, etc, but the embodiments of the present disclosure are not limited thereto.

The third plate 600 may be formed of the same material as the first plate 400, but is not limited thereto. The third plate 600 can protect the second region SR of the display panel 100.

The printed circuit board FPCB may overlap the first region MR. The printed circuit board FPCB may be disposed or attached to the second plate 500 on the first region MR. A fifth bonding layer PSA5 may be disposed between the printed circuit board FPCB and the second plate 500 of the first region MR.

The display controller DSIP may be disposed at one side of the printed circuit board FPCB. One surface of the printed circuit board FPCB may be a surface opposite to the other surface attached to the second plate 500. FIG. 7 shows that only the display controller DSIP is disposed on the one surface of the printed circuit board FPCB, but the embodiments of the present disclosure are not limited thereto, and the touch controller and the like may also be disposed together on the one surface of the printed circuit board FPCB.

The display panel 100 may include the third region BR, and the display panel 100 may be bent in the third region BR. Accordingly, a bezel area of the display panel 100 can be reduced.

The printed circuit board FPCB may be attached to an end portion of the bent display panel 100. The printed circuit board FPCB may extend along the end portions and a side surface of the second region SR of the display panel 100, a side surface of the third plate 600, and a lower surface of the second plate 500. The printed circuit board FPCB may be fixedly attached to the second plate 500 through the fifth bonding layer PSA5. The fifth bonding layer PSA5 may be disposed between the second plate 500 and the printed circuit board FPCB. The lower surface of the second plate 500 may be fixedly attached to the printed circuit board FPCB through the fifth bonding layer PSA5.

Accordingly, the thickness of the display apparatus 10 can be reduced, and the movement of the printed circuit board (FPCB) can be minimized or reduced. Furthermore, it is possible to minimize or reduce physical interference between the printed circuit board FPCB and set components, reinforce durability of the display apparatus, and extend the lifetime of the display apparatus.

The display apparatus 10 may further include a buffer member BF disposed on the side surfaces of the stacked members of the display apparatus 10.

The buffer member BF may be disposed around the edge of the display apparatus 10. The buffer member BF may be disposed in the non-display area NDA. The buffer member BF may be disposed across three surfaces of the display apparatus 10. The buffer member BF may be disposed on one side and the other side of the display apparatus 10 in the first direction DR1 and one side thereof in the second direction DR2. The buffer member BF may be formed integrally, but is not limited thereto.

The buffer member BF may be disposed on side surfaces of each of the display panel 100, the first plate 400 and the second plate 500. The buffer member BF may cover each of the display panel 100, the polarizing layer 200, the first plate 400, the second plate 500, the first bonding layer PSA1, the second bonding layer PSA2, and the third bonding layer PSA3, but is not limited thereto. The buffer member BF may cover a portion of the lower surface of the second plate 500. In addition, the buffer member BF may cover a portion of a side surface of the optical adhesive layer OCA.

The buffer member BF may be formed of a resin, but is not limited thereto. By arranging the buffer member BF, external vibrations or impacts transferred to each stacked member can be mitigated. For example, when each stacked member of the display apparatus 10 is stored in a different component and moved, the buffer member BF can mitigate impacts that may occur during storage or vibrations, impacts, or the like that may occur during movement. Accordingly, damage to each stacked member of the display apparatus 10 can be suppressed or prevented, thereby improving the reliability of the display apparatus 10.

The display apparatus 10 may further include a metal protection film MPF and an impact protection film SPF that are disposed on the lower surface of the second plate 500. For example, the metal protection film MPF may be disposed between the second plate 500 and the impact protection film SPF. Here, the lower surface of the second plate 500 refers to a surface opposite an upper surface facing the first plate 400.

The metal protection film MPF can protect the second plate 500 from external impacts, etc. Although not limited thereto, the metal protection film MPF may be formed of two layers. For example, the metal protection film MPF may be formed of more or less layers. A first layer MPF1 and a second layer MPF2 may be sequentially stacked and disposed. The first layer MPF1 may be disposed between the second layer MPF2 and the second plate 500. The second layer MPF2 may be disposed between the first layer MPF1 and the impact protection film SPF.

The first layer MPF1 may include an adhesive, but is not limited thereto. The second layer MPF2 may be formed of a film capable of protecting the second plate 500, but is not limited thereto.

At least a portion of the impact protection film SPF may be disposed to overlap the printed circuit board FPCB in the thickness direction (third direction DR3). For example, the at least a portion of the impact protection film SPF may be disposed between the printed circuit board FPCB and the buffer member BF.

The impact protection film SPF may cover a portion of the second plate 500 exposed without being covered by the metal protection film MPF and the buffer member BF in the area overlapping the printed circuit board FPCB.

The impact protection film SPF may be disposed between the printed circuit board FPCB and the second plate 500 and between the printed circuit board FPCB and the buffer member BF. The impact protection film SPF may be disposed to be spaced apart from the buffer member BF. The impact protection film SPF can prevent or suppress the printed circuit board FPCB from being in contact with the second plate 500 and the buffer member BF.

A portion of the impact protection film SPF may be disposed on the metal protection film MPF, but is not limited thereto. In this case, the portion of the impact protection film SPF may overlap the metal protection film MPF in the thickness direction (third direction DR3).

In the area overlapping the printed circuit board FPCB, the impact protection film SPF may protrude outward farther than the display panel 100. specifically, in the area overlapping the printed circuit board FPCB, the impact protection film SPF may protrude farther than the display panel 100 in the first direction DR1. Although not limited thereto, in the area overlapping the printed circuit board FPCB, the impact protection film SPF may protrude farther than the polarizing layer 200, the first plate 400, and the second plate 500 in the first direction DR1.

The cover layer 300 may protrude farther than the printed circuit board FPCB in the first direction DR1, but is not limited thereto. For example, the cover layer 300 may protrude outward farther than the printed circuit board FPCB in the first direction DR1, but is not limited thereto.

In the area overlapping the printed circuit board FPCB, the impact protection film SPF may protrude outward farther than the metal protection film MPF. That is, in the area overlapping the printed circuit board FPCB, the impact protection film SPF may protrude farther than the metal protection film MPF toward the end of the display apparatus 10. For example, in the area overlapping the printed circuit board FPCB, the buffer member BF may be disposed on the lower surface near the end portion of the second plate 500, and the metal protection film MPF may be disposed to be spaced apart from the buffer member BF.

That is, the buffer member BF may be primarily disposed on the side surfaces of the stacked members, but may also be disposed on the lower surface near the end portion of the second plate 500 during the forming process. The metal protection film MPF may be disposed on the lower surface of the second plate 500 and may expose a portion of the lower surface near the end portion of the second plate 500. Accordingly, a space for the buffer member BF to be stably disposed may be provided. The metal protective film MPF may be disposed to be spaced apart from the buffer member BF.

The impact protection film SPF may extend farther than the metal protection film MPF in the first direction DR1 and protrude farther than the buffer member BF in the first direction DR1. The impact protection film SPF may overlap the buffer member BF in the thickness direction (third direction DR3) in the area overlapping the printed circuit board FPCB in the thickness direction (third direction DR3). That is, the impact protection film SPF may be disposed between the printed circuit board FPCB and the buffer member BF.

The impact protection film SPF can absorb and mitigate external impacts. In addition, the impact protection film SPF may be formed of an insulation material with high electrical resistance. However, the embodiments of the present disclosure are not limited thereto.

Since the impact protection film SPF is disposed between the printed circuit board FPCB and the exposed portion of the second plate 500, direct contact between the printed circuit board FPCB and the exposed second plate 500 can be prevented or suppressed. The impact protection film SPF may be disposed between the printed circuit board FPCB and the metal protection film MPF.

Since the impact protection film SPF is formed of an insulation material, the printed circuit board FPCB and the second plate 500 may be electrically insulated. Accordingly, the printed circuit board FPCB can operate stably, and electrical errors and defects can be suppressed or prevented.

By arranging the impact protection film SPF between the printed circuit board FPCB and the buffer member BF, direct contact between the printed circuit board FPCB and the buffer member BF can be prevented or suppressed. That is, even when the display apparatus 10 shakes and the printed circuit board FPCB shakes, the impact protection film SPF can mitigate a direct impact of the printed circuit board FPCB on the buffer member BF.

Accordingly, damage to the buffer member BF can be suppressed or prevented, allowing for more efficient mitigation of external vibrations and impacts through the buffer member BF.

In addition, even when the printed circuit board FPCB is attached to the second plate 500 and a distance between the second plate 500 and the buffer member BF decreases, by arranging the impact protection film SPF, it is possible to more smoothly suppress or prevent the printed circuit board FPCB from being in direct contact with the second plate 500 and the buffer member BF.

Consequently, by arranging the impact protection film SPF, the reliability of the display apparatus 10 can be improved, the lifetime of the display apparatus 10 can be extended, low power consumption of the display apparatus 10 can be achieved, and furthermore, the power consumption of the display apparatus 10 can be reduced.

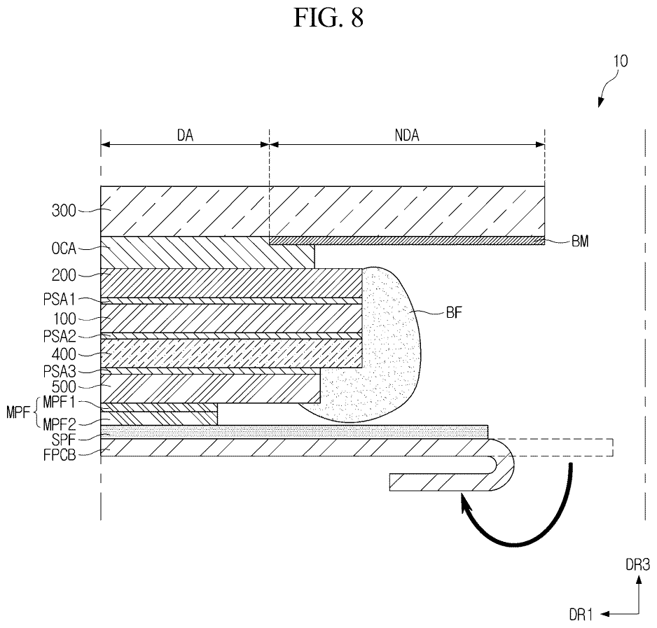

FIG. 8 is a cross-sectional view of a display apparatus according to an example embodiment.

As illustrated in FIGS. 6 and 8, when the display apparatus 10 is stored in a housing or the like, a portion of the printed circuit board FPCB may be bent.

Specifically, as shown in FIG. 6, a portion of the printed circuit board FPCB may protrude outward farther than the cover layer 300 in the first direction DR1. The printed circuit board FPCB protruding outward farther than the cover layer 300 may be bent downward in the third direction DR3 and disposed to overlap the cover layer 300 in the thickness direction (third direction DR3).

By bending the printed circuit board FPCB protruding outward farther than the cover layer 300 and disposed to overlap the cover layer 300, the display apparatus 10 can be prevented or suppressed from colliding with the housing or the like during the process of being stored in the housing or the like, and the display apparatus 10 can be stored more smoothly in the housing or the like.

A display apparatus according to various example embodiments of the present disclosure may be described as follows.

According to various example embodiments of the present disclosure, there is provided a display apparatus including a display panel, a printed circuit board attached to the display panel, at least one plate disposed below the display panel, a buffer member disposed on side surfaces of each of the display panel and the at least one plate, and an impact protection film disposed on a lower surface of the at least one plate, in which at least a portion of the impact protection film is disposed between the printed circuit board and the buffer member.

According to various example embodiments of the present disclosure, the at least one plate may include a first plate below the display panel and a second plate below the first plate, the impact protection film may be on the lower surface of the second plate.

According to various example embodiments of the present disclosure, the impact protection film may protrude outward farther than the buffer member.

According to various example embodiments of the present disclosure, the impact protection film may protrude outward farther than the display panel, the first plate, and the second plate.

According to various example embodiments of the present disclosure, the display apparatus may further include a cover layer disposed on the display panel, in which the cover layer may protrude outward farther than the impact protection film.

According to various example embodiments of the present disclosure, the impact protection film may overlap the buffer member in the thickness direction in an area overlapping the printed circuit board in a thickness direction.

According to various example embodiments of the present disclosure, the display apparatus may further include a display area in which a screen is displayed and a non-display area disposed around the display area, in which the buffer member may be disposed in the non-display area.

According to various example embodiments of the present disclosure, the display apparatus may further include a metal protective film disposed on a lower surface of the second plate, in which the impact protection film may protrude outward farther than the metal protective film in an area overlapping the printed circuit board in a thickness direction.

According to various example embodiments of the present disclosure, the buffer member may be disposed on the lower surface of the second plate, and the metal protective film may be disposed to be spaced apart from the buffer member.

According to various example embodiments of the present disclosure, a portion of the second plate exposed without being covered by the metal protective film and the buffer member may be covered by the impact protection film in the area overlapping the printed circuit board in the thickness direction.

According to various example embodiments of the present disclosure, the impact protection film may be disposed between the printed circuit board and the exposed portion of the second plate.

According to various example embodiments of the present disclosure, the impact protection film may be formed of an insulation material.

According to various example embodiments of the present disclosure, the impact protection film may be disposed to be spaced apart from the buffer member.

According to various example embodiments of the present disclosure, the display apparatus may further comprise a polarizing layer disposed on the display panel, wherein the polarizing layer includes a first phase retardation layer, a second phase retardation layer on the first phase retardation layer, and a polarizer on the second phase retardation layer.

According to various example embodiments of the present disclosure, the display apparatus may further comprise a third plate disposed below the second plate and formed of the same material as the first plate.

According to various example embodiments of the present disclosure, the display panel may comprise a first region, a second region that overlap each other in the thickness direction, and a third region between the first region and the second region, and the third plate may be disposed on the second region.

According to various example embodiments of the present disclosure, the first plate may include a material capable of supporting the display panel.

Although example embodiments have been described above with reference to the accompanying drawings, those skilled in the art to which the present disclosure pertains will be able to understand that the above-described technical configurations can be carried out in other specific forms without changing or departing from the technical spirit or concepts thereof. Accordingly, it should be understood that the above-described embodiments are illustrative and not restrictive in all respects. In addition, a protective scope of the embodiments may be determined by the appended claims and their equivalents rather than detailed description. In addition, the meaning and scope of the claims and all changed or modified forms derived from the equivalent concept thereof should be construed as being included in the scope of the present disclosure.

What is claimed is:

1. A display apparatus, comprising:
a display panel;
a printed circuit board attached to the display panel;
at least one plate below the display panel;
a buffer member on side surfaces of each of the display panel and the at least one plate; and
an impact protection film on a lower surface of the at least one plate,
wherein at least a portion of the impact protection film is disposed between the printed circuit board and the buffer member.

2. The display apparatus of claim 1, wherein:
the at least one plate includes a first plate below the display panel and a second plate below the first plate; and
the impact protection film is on the lower surface of the second plate.

3. The display apparatus of claim 2, wherein the impact protection film protrudes outward farther than the buffer member.

4. The display apparatus of claim 3, wherein the impact protection film protrudes outward farther than the display panel, the first plate, and the second plate.

5. The display apparatus of claim 4, further comprising a cover layer on the display panel,
wherein the cover layer protrudes outward farther than the impact protection film.

6. The display apparatus of claim 1, wherein the impact protection film overlaps the buffer member in a thickness direction in an area overlapping the printed circuit board in a thickness direction.

7. The display apparatus of claim 6, further comprising a display area in which a screen is displayed and a non-display area disposed around the display area,
wherein the buffer member is disposed in the non-display area.

8. The display apparatus of claim 2, further comprising a metal protective film on a lower surface of the second plate,
wherein the impact protection film protrudes outward farther than the metal protective film in an area overlapping the printed circuit board in a thickness direction.

9. The display apparatus of claim 8, wherein the buffer member is disposed on the lower surface of the second plate, and the metal protective film is disposed to be spaced apart from the buffer member.

10. The display apparatus of claim 9, wherein a portion of the second plate exposed without being covered by the metal protective film and the buffer member is covered by the impact protection film in the area overlapping the printed circuit board in the thickness direction.

11. The display apparatus of claim 10, wherein the impact protection film is disposed between the printed circuit board and the exposed portion of the second plate.

12. The display apparatus of claim 11, wherein the impact protection film is formed of an insulation material.

13. The display apparatus of claim 1, wherein the impact protection film is disposed to be spaced apart from the buffer member.

14. The display apparatus of claim 1, further comprising a polarizing layer disposed on the display panel,
wherein the polarizing layer includes a first phase retardation layer, a second phase retardation layer on the first phase retardation layer, and a polarizer on the second phase retardation layer.

15. The display apparatus of claim 2, further comprising a third plate disposed below the second plate and formed of a same material as the first plate.

16. The display apparatus of claim 15, wherein:
the display panel comprises a first region and a second region that overlap each other in a thickness direction, and a third region between the first region and the second region; and
the third plate is disposed on the second region.

17. The display apparatus of claim 2, wherein the first plate includes a material capable of supporting the display panel.
